(19) United States
(12) Patent Application Publication
(10) Pub. No.: US 2026/0107608 A1
(43) Pub. Date: Apr. 16, 2026

(54) METHODS AND DEVICES FOR LIGHT EMITTING DEVICE WITH FRAME

(71) Applicant: Lumileds LLC, San Jose, CA (US)

(72) Inventors: Grigoriy Basin, San Francisco, CA (US); Yu-Chen Shen, Sunnyvale, CA (US); Jeff DiMaria, Scotts Valley, CA (US)

(73) Assignee: Lumileds LLC, San Jose, CA (US)

(21) Appl. No.: 18/917,588

(22) Filed: Oct. 16, 2024

(51) Int. Cl. H01L 33/60; H01L 25/075; H01L 33/48

(52) U.S. Cl. CPC H10H 20/856; H10H 20/8506; H10W 90/00; H10H 20/0363

(57) ABSTRACT

A LED light source includes a frame with side walls having reflective interior surfaces that define sides of an internal cavity. The frame may be placed above an LED array to contain the light of the array. One or more light transmitting layers may be placed above the frame to further or maintain containment of the light and/or to support an optical element above the frame. The optical element may direct the light of the LED array to provide a narrowed radiation pattern that may be advantageously employed for backlighting LCOS and other displays.

### FIELD OF THE INVENTION

The invention relates generally to LED light sources and to displays comprising such light sources.

### BACKGROUND

Semiconductor light emitting diodes and laser diodes (collectively referred to herein as “LEDs”) are among the most efficient light sources currently available. The emission spectrum of an LED typically exhibits a single narrow peak at a wavelength determined by the structure of the device and by the composition of the semiconductor materials from which it is constructed. By suitable choice of device structure and material system, LEDs may be designed to operate at ultraviolet, visible, or infrared wavelengths. LEDs may be combined with one or more wavelength converting materials (generally referred to herein as “phosphors”) that absorb light emitted by the LED and in response emit light of a longer wavelength.

Inorganic LEDs and phosphor converted LEDs may be used to create different types of displays including, for example, augmented-reality (AR) displays, virtual-reality (VR) displays, and mixed-reality (MR) displays.

Automotive direct imaging and LCOS AR/VR system optics need a high luminance light source. To increase the luminance, the light emitting area may be minimized, and the radiation pattern may be narrowed.

### SUMMARY

A display system may comprise, for example, a liquid crystal on silicon (LCOS) array backlit by light emitted by a light source comprising (e.g., red, green, and blue) LEDs. The light emitted by the LEDs is typically collected by a collection optic or optical system that directs the light to the LCOS array. An LED die typically emits in a wide radiation pattern. The inventors recognize that in such an LED backlit display system light emitted by the LEDs at wide angles may not be collected by the collection optic or optical system or may be incident on the collection optic or optical system at undesirably large angles.

This specification discloses LED light sources providing a narrowed radiation pattern suitable for backlighting LCOS and other displays. In embodiments of the invention, a frame may be placed above one or more LEDs. Alone or in conjunction with one or more light transmitting layers, the frame may contain the light to decrease or narrow the light emitting area of the light emitting device. For example, a light transmitting layer may be disposed between the frame and an optical element, such as a lens, to direct or help contain the light of the one or more LEDs.

### BRIEF DESCRIPTION OF THE DRAWINGS

FIG. 1 shows a cross-section of a support structure on a tape.

FIG. 2 shows a cross-section of a segmented support layer on a tape.

FIG. 3 shows a cross-section of a reflective material on a segmented support layer.

FIG. 4 shows a cross-section of a planarized segmented support layer and reflective sidewalls.

FIG. 5 shows a cross-section of a segmented support layer attached to an optical element.

FIG. 6 shows a cross-section of a frame.

FIG. 7 shows a cross-section of a frame attached to a bonding layer.

FIG. 8 shows a cross-section of a frame attached to a segmented support layer with an optical element.

FIG. 9 shows a cross-section of a light emitting device including an array of LEDs, a frame, a support layer, and an optical element.

FIG. 10 shows a cross-section of a support layer attached to a frame without an optical element.

FIG. 11 shows a cross-section of a light emitting device including an array of LEDs, a frame, and a support layer.

FIG. 12 shows a cross-section of a support structure with a sacrificial sheet on a tape.

FIG. 13 shows a cross-section of a segmented support layer with a sacrificial layer on a tape.

FIG. 14 shows a cross-section of a reflective material on a segmented support layer with a sacrificial layer.

FIG. 15 shows a cross-section of a planarized segmented support layer and reflective sidewalls.

FIG. 16 shows a cross-section of a segmented support layer attached to an optical element.

FIG. 17 shows a cross-section of a frame.

FIG. 18 shows a cross-section of a frame attached to a bonding layer.

FIG. 19 shows a cross-section of a frame attached to a segmented support layer with an optical element.

FIG. 20 shows a cross-section of a light emitting device including an array of LEDs, a frame, a support layer, and an optical element.

FIG. 21 shows a cross-section of a light emitting device including an array of LEDs, a frame, and a support layer.

FIG. 22 shows a cross-section of a light emitting device including an array of LEDs, a frame, a support layer with a reflector extending into an optical element.

FIG. 23 shows a plan view of a light emitting device including an array of LEDs and a frame.

### DETAILED DESCRIPTION

The following detailed description should be read with reference to the drawings, in which identical reference numbers refer to like elements throughout the different figures. The drawings, which are not necessarily to scale, depict selective embodiments and are not intended to limit the scope of the invention. The detailed description illustrates by way of example, not by way of limitation, the principles of the invention. This description will clearly enable one skilled in the art to make and use the invention, and describes several embodiments, adaptations, variations, alternatives and uses of the invention.

As used in this specification and the appended claims, the singular forms “a,” “an,” and “the” include plural referents unless the context clearly indicates otherwise. Also, the term “parallel” is intended to mean “substantially parallel” and to encompass minor deviations from parallel geometries. The term “vertical” refers to a direction parallel to the force of the earth's gravity. The term “horizontal” refers to a direction perpendicular to “vertical.” The term “on” means to be disposed to overlap (e.g., vertically) and/or to be directly in contact with.

To resolve some of the problems stated in the Background section above, a frame structure may be placed over one or more LEDs. This frame structure may be used with one or more light transmitting layers to ensure proper radiation characteristics of the light emitting device. Processes described below may follow steps shown in sequential order. Alternatively, one or more steps may be omitted, added, and/or rearranged according to embodiments of the invention.

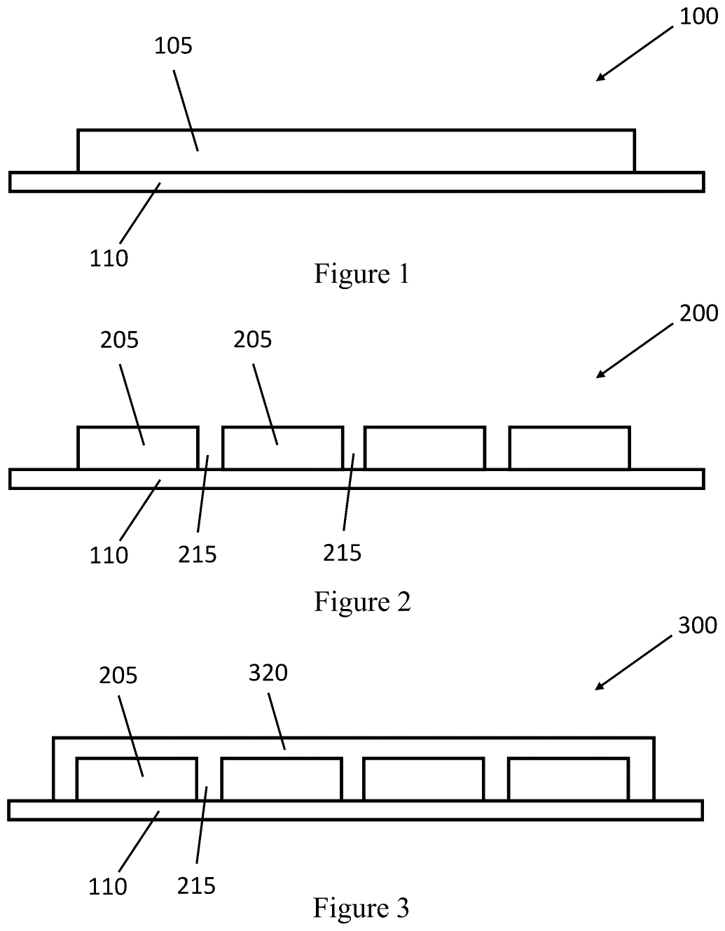

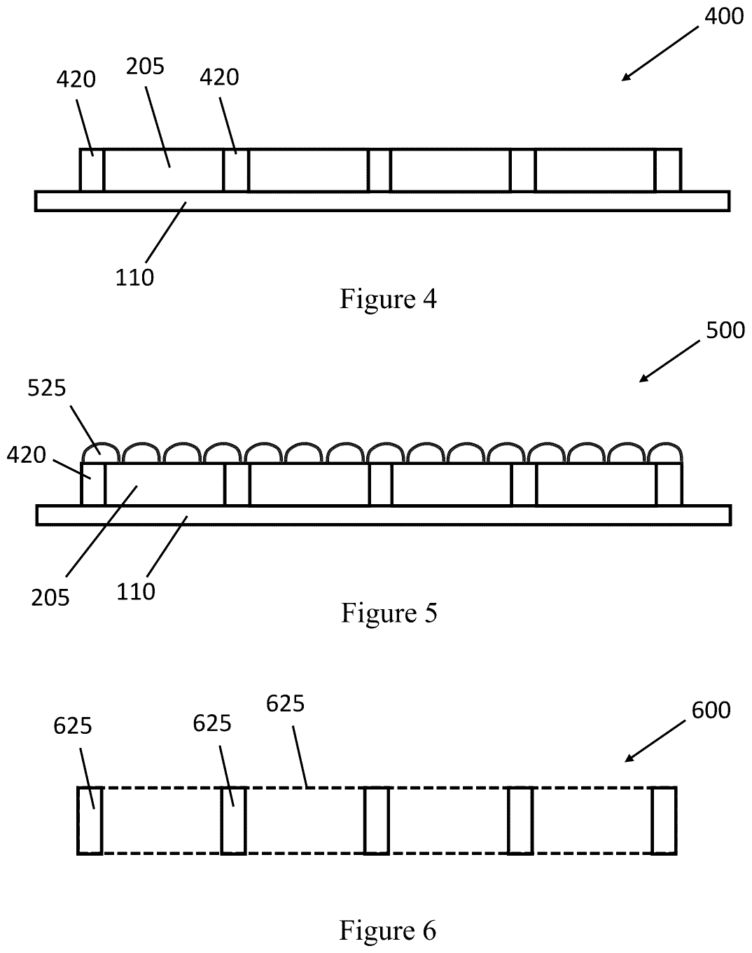

FIGS. 1-8 show a process and devices according to embodiments of the invention. At 100, a support structure 105 is disposed on a tape 110 as a continuous layer. The support structure 105 may be transparent silicone or any other transparent material. At 200 the support structure 105 is segmented into a support layer 205 comprising segments disposed on a same plane as each other and/or with even topmost surfaces as each other that are spaced apart and discontinuous from each other. The segmentation may be done by sawing, such as with a thin blade having a nonzero width of 50 microns or less. The segmentation may be done by any other appropriate means, such as lasering. The segmentation may leave gaps 215 separating parts of the support layer 205 from each other, which may have nonzero widths of 50 microns or less. Once the support layer 205 is formed, at 300 a reflective material 320 may be molded or otherwise disposed over the support layer 205 and/or on the tape 110. The reflective material 320 fills the gaps 215 partially or completely. At 400 this structure is planarized so that most or all of the reflective material 320 disposed on the support layer 205 is removed from the top of the support layer 205, while remaining in the gaps 215 to form a reflector 420 disposed on the sidewalls of segments of the support layer 205. The reflector 420 (and the gaps 215 in which it is disposed) may form a grid. At 500 an optical element 525 is disposed on top of the support layer 205. The optical element 525 may be at least one of a lens, microlenses, metalenses, polarizers, clear covers (like glass plates or a layer of silicone) and the like. The optical element 525 may have a flat surface disposed on the support layer 205 and/or the reflector 420. A light emitting surface of the optical element 525 opposite the flat surface disposed on the support layer 205 may be flat or not. The optical element 525 may be molded onto the support layer 205 and/or the reflector 420, and/or adhered by any other appropriate method. The optical element 525 may be a continuous layer or it may include individual structures spaced apart and discontinuous from each other by gaps. For example, the optical element 525 may be an array of lens or microlens that spaced apart from each other by gaps without being connected with one another. The optical element 525 may include lens/microlens on a top surface and/or lens/microlens on a bottom surface facing the LEDs 945 and opposite the top surface.

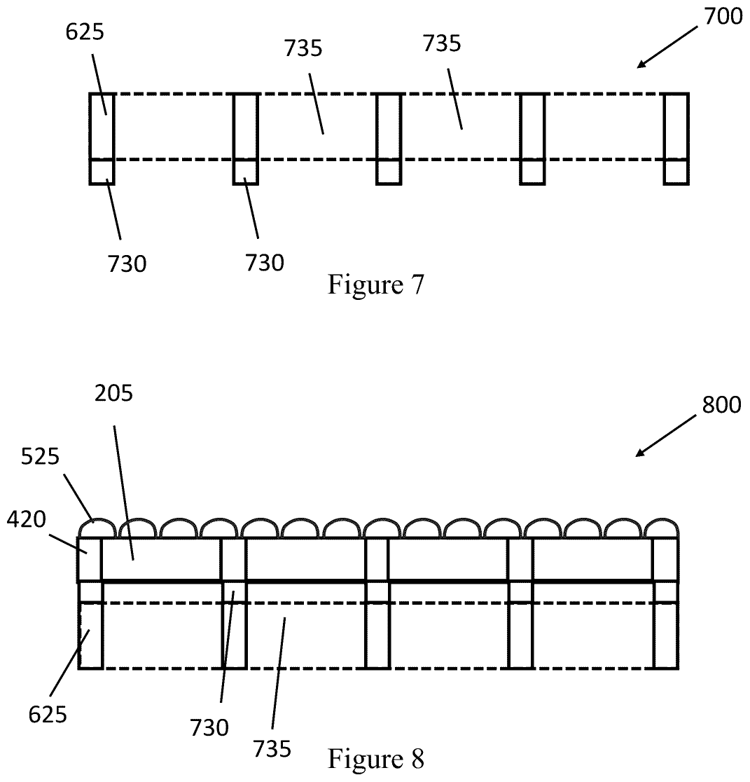

At 600 the frame 625 may be formed and/or obtained. FIG. 6 show a cross section where parts of the frame 625 are spaced out from each other, but the frame 625 may be a single continuous piece forming a symmetric grid with equal or unequal rows and columns, a grid which is similar or the same as the shape and/or the width/length of reflector 420. For ease of understanding, the dashed lines indicate the part of the frame 625 on a second plane behind the first plane in which the cross-section of the solid-lined pillars of frame 625 is taken. The dashed line may indicate a solid sheet of frame 625 which connect the spaced apart pillars of frame 625 with each other in a continuous structure. The frame 625 may have a same or different height than the reflector 420. The frame 625 may form cavities 735 of air spaced apart and/or isolated from each other, and may be defined by the interior walls of the frame 625. The frame 625 may be or include at least one of ceramic, white ceramic, aluminum, silicon, or other reflective material. The frame 625 may be formed separately from the structure depicted in FIG. 5. At 700, the ceramic frame 625 is disposed on a bonding layer 730. The bonding layer 730 may be a gravure coated film that is 1-2 microns thick. The bonding layer 730 may be or include silicone. The bonding layer 730 may include portions directly in contact with the frame 625 with openings matching the cavities 735. The bonding layer 730 may form a continuous layer, such as having a grid shape matching or substantially matching the grid of the frame 625, although this is not a requirement and the bonding layer 730 may be formed of regions discontinuous from and spaced apart from each other. At 800 the structure of FIG. 7 may be inverted so that bonding layer 730 faces support layer 205 and reflector 420 and bonds and/or adhere the frame 625 to them. Finally, at 900 the frame 625 is disposed over and bonded to an LED array. The LED array may include multiple LEDs 945 disposed on a substrate 940. Each LED 945 may be surrounded by one or more light absorbing element 935 and may have a wavelength converting layer 950 disposed on its top light emitting surface. For ease of understanding, the dotted lines indicate the part of the light absorbing element 935 on a second plane behind the first plane in which the cross-section of the solid-lined pillars of light absorbing element 935 is taken. The dotted line may indicate a solid sheet of light absorbing element 935 which connect the spaced apart pillars of light absorbing element 935 with each other in a continuous structure. The number of LEDs 945 in the array may match the number of cavities 735 in the frame 625. The reflector 420, the frame 625, and the sidewalls of light absorbing element 935 may be aligned or substantially aligned with each other, although this is not a requirement. The reflector 420, the frame 625, and the light absorbing element 935 may have different or same vertical heights as each other, and may have different or same horizontal width as each other. The light absorbing element 935 may be silicone and may be a different material than one or both of the frame 625 and the reflector 420. The support layer 205 may serve to support the optical element 525 on the frame 625, providing a level of rigidity over the cavities 735 of the frame 625. Each cavity 735 may be bounded by the frame 625 and opposing bonding layers 730, for example, and may be filled partially or entirely with at least one of vacuum, air, or other gas. Alternatively or additionally, the cavity 735 may be partially or entirely filled with at least one of phosphors, quantum dots, binders, and non-phosphorous scattering particles and material. Each cavity 735 may be horizontally wider than the LED 945 and/or wavelength converting layer 950. Each cavity 735 may be disposed directly above (e.g., overlapping in a vertical direction) a portion or an entirety of an LED 945 and/or a segment of the wavelength converting layer 950, and each segment of the support layer 205 may likewise be disposed directly above a portion or an entirety of an LED 945 and/or a segment of the wavelength converting layer 950. Each segment of the support layer 205 may be disposed directly above a portion or an entirety of a single cavity 735. The frame 625 may serve to contain the light from the LEDs 945 so that they are not spread out when they are emitted from the light emitting device. The frame 625 may also protect the LEDs during manufacturing.

Alternatively or additionally, multiple frames 625 and support layers 205 with reflectors 420 may be stacked on top of each other above the LEDs 945. For example, the multiple frames 625 and multiple support layers 205 may be alternately stacked with each other above the LEDs 945, such as from two to ten of each of frames 625 and support layers 205, such as from two to five of each. Furthermore, an optical element 525 may be disposed on the topmost support layer 205, so that there are multiple frames 625 and support layers 205 between the optical element 525 and the LEDs 945. Individual bonding layers 730 may be disposed between these support layers 205 and frames 625.

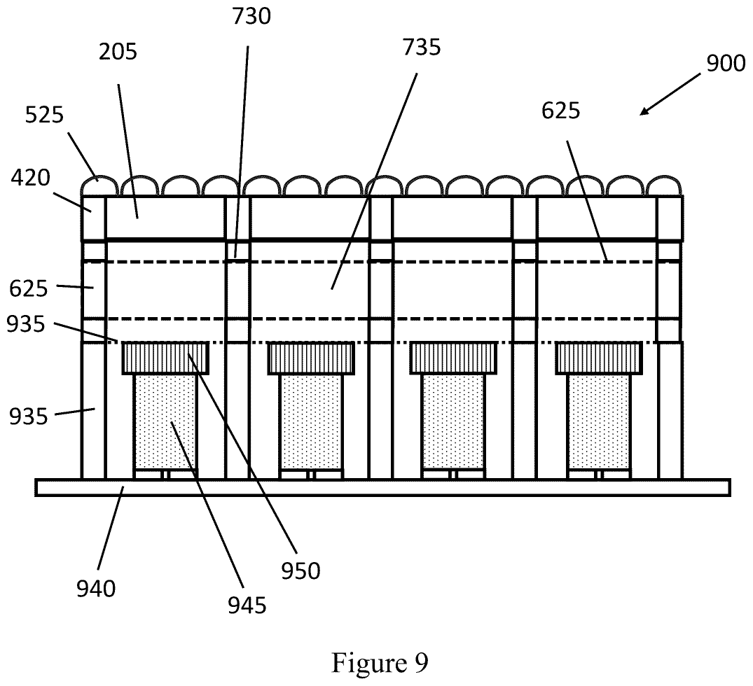

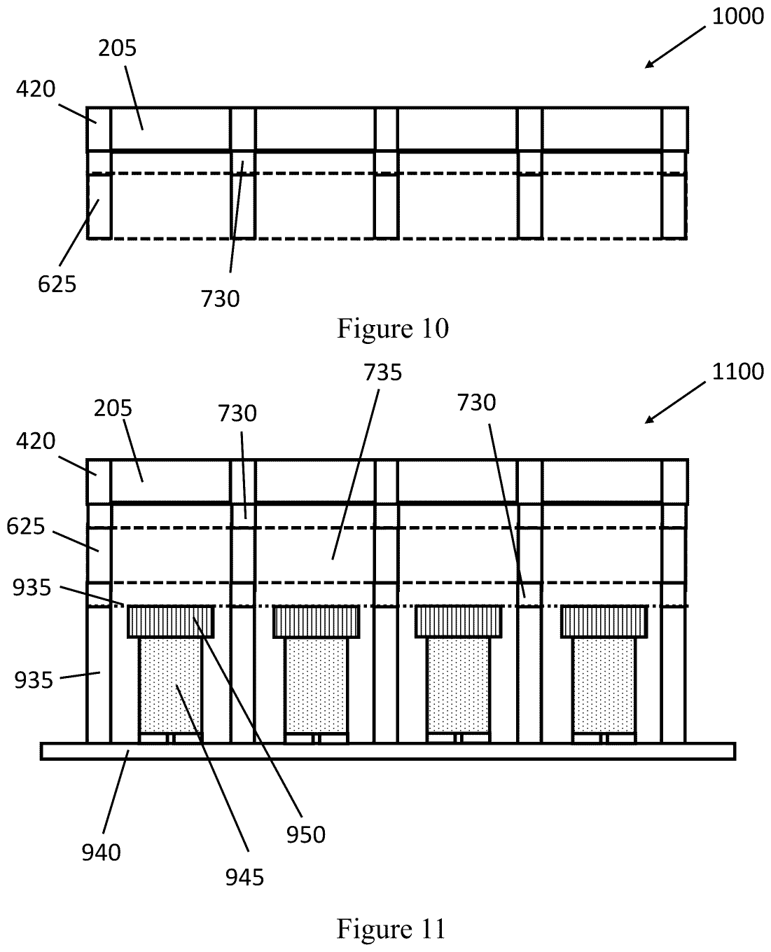

According to embodiments of the invention, processes forming a device may follow steps shown in FIGS. 1-4, 6, 7 and FIGS. 10-11, for example sequentially, starting from FIG. 1 and ending in FIG. 11. In this process optical element 525 is not disposed on top of reflector 420 and support layer 205. At 1000, the structure obtained in 700 at FIG. 7 is inverted and bonded to the support layer 205 and reflector 420 by the bonding layer 730. The resulting structure from FIG. 10 is then disposed on top of the LEDs at 1100, in a same or similar way as in FIG. 9. The resulting device in FIG. 11 does not have an optical element 525 disposed on top of the support layer 205 and reflector 420. Instead, the flat surface provided by the top of the support layer 205 may serve as the light emitting surface of the light emitting device, rather than the surface of any optical element. Along with the frame 625, the support layer 205 with the reflector 420 may contain the light emitted from the LEDs 945 to narrow the radiation pattern and reduce the light emitting area of the light emitting device.

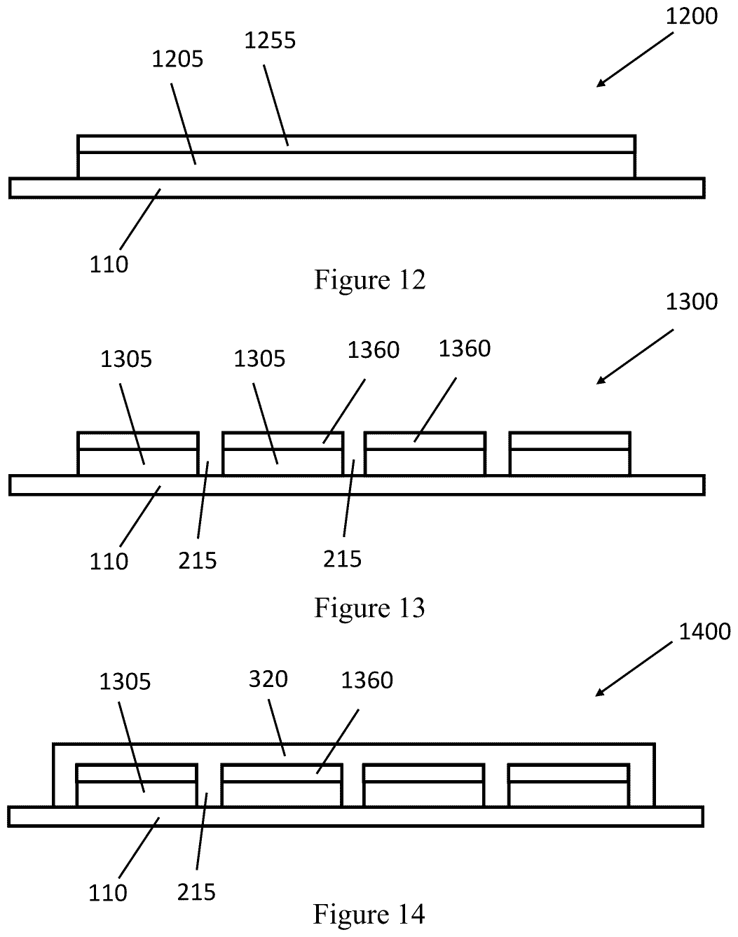

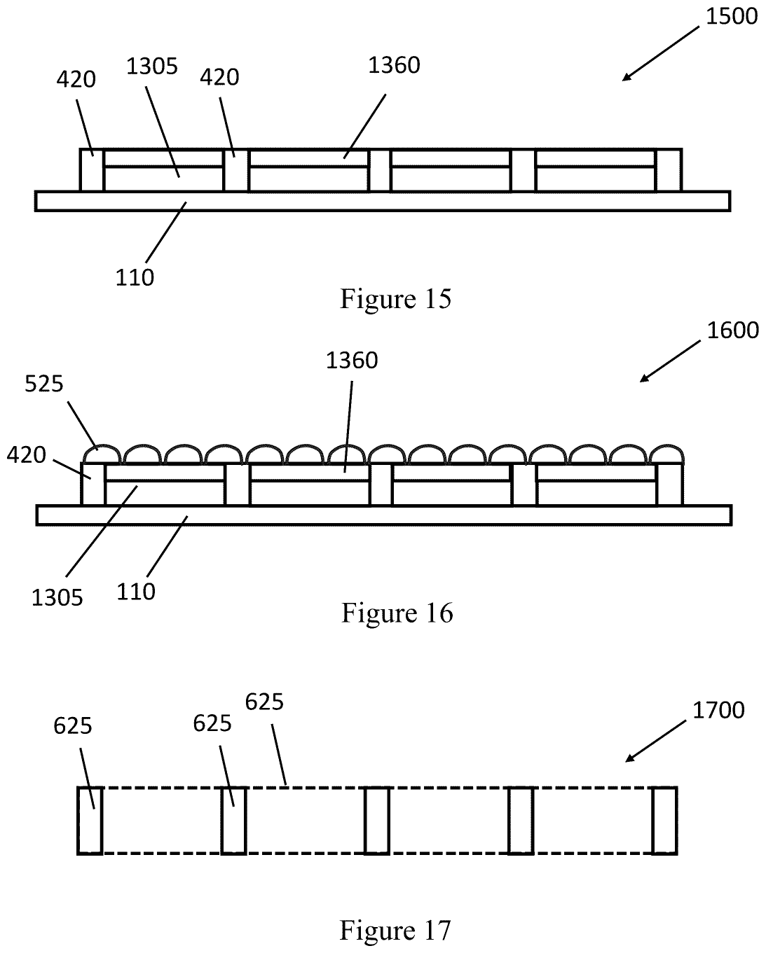

According to embodiments of the invention, processes forming a device may follow steps shown in FIGS. 12-20. At 1200, a glass sheet 1205 with a sacrificial sheet 1255 is disposed on a tape 110 as a continuous layer. The glass sheet 1205 and sacrificial sheet 1255 may have a same or similar horizontal width and may be in direct contact with each other. The glass sheet 2015 may be thicker than the sacrificial sheet 1255 in the vertical direction, although this is not a requirement. The glass sheet 1205 and the sacrificial sheet 1255 may both be transparent and may be or include different materials from each other. At 1300 the glass sheet 1205 and the sacrificial sheet 1255 are segmented into a glass layer 1305 and sacrificial layer 1360 each comprising segments disposed on a same plane as each other and/or with even topmost surfaces as each other that are spaced apart and discontinuous from each other. The segmentation may be done by sawing, such as with a thin blade having a nonzero width of 50 microns or less. The segmentation may be done by any other appropriate means, such as lasering. The segmentation may leave gaps 215 separating parts of the glass layer 1305 and sacrificial layer 1360 from each other, which may have nonzero widths of 50 microns or less. Once the glass layer 1305 and sacrificial layer 1360 are formed, at 1400 a reflective material 320 may be molded or otherwise disposed over the glass layer 1305 and sacrificial layer 1360 and/or on the tape 110. The reflective material 320 fills the gaps 215 partially or completely. At 1400 this structure is planarized so that most or all of the reflective material 320 disposed on the glass layer 1305 and sacrificial layer 1360 is removed from the top of the sacrificial layer 1360, while remaining in the gaps 215 to form a reflector 420 disposed on the sidewalls of segments of glass layer 1305 and sacrificial layer 1360. The planarization may remove none, some, or all of the sacrificial layer 1360. In the instance where the planarization removes all of the sacrificial layer 1360, the top surface of the glass layer 1305 may be exposed after planarization. The reflector 420 (and the gaps 215 in which it is disposed) may form a grid. At 1600 an optical element 525 is disposed on top of the glass layer 1305 and/or any remaining sacrificial layer 1360 to be in direct contact with either the top layer of the glass layer 1305 or the remaining sacrificial layer 1360. The optical element 525 may be at least one of a lens, microlenses, metalenses, polarizers, clear covers (like glass plates or a layer of silicone) and the like. The optical element 525 may have a flat surface disposed on the support layer 205 and/or the reflector 420. The optical element 525 may be molded onto the support layer 205 and/or the reflector 420, and/or adhered by any other appropriate method.

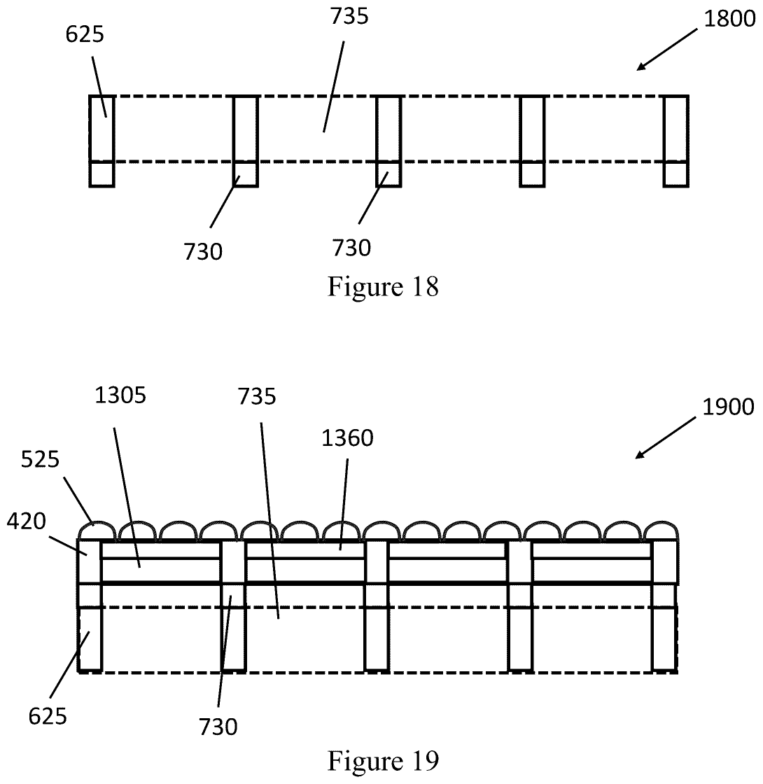

At 1700 the frame 625 may be formed and/or obtained. FIG. 17 show a cross section where parts of the frame 625 are spaced out from each other, but the frame 625 may be a single continuous piece forming a symmetric grid with equal or unequal rows and columns, a grid which is similar or the same as the shape and/or the width/length of reflector 420. The frame 625 may have a same or different height than the reflector 420. The frame 625 may form cavities 735 of air spaced apart and/or isolated from each other. The frame 625 may be or include at least one of ceramic, white ceramic, aluminum, silicon, or other reflective material. The frame 625 may be formed separately from the structure depicted in FIG. 16. At 1800, the ceramic frame 625 is disposed on a bonding layer 730. The bonding layer 730 may be a gravure coated film that is 1-2 microns thick. At 1900 the structure of FIG. 18 may be inverted so that bonding layer 730 faces glass layer 1305 and sacrificial layer 1360 and reflector 420 and bonds the frame 625 to them. Finally, at 2000 the frame 625 is disposed over and bonded to an LED array. The LED array may include multiple LEDs 945 disposed on a substrate 940. Each LED 945 may be surrounded by one or more light absorbing element 935 and may have a wavelength converting layer 950 disposed on its top light emitting surface. The number of LEDs 945 in the array may match the number of cavities 735 in the frame 625. The reflector 420, the frame 625, and the light absorbing element 935 may be aligned or substantially aligned with each other, although this is not a requirement. The glass layer 1305 and sacrificial layer 1360 may serve to support the optical element 525 on the frame 625, providing a level of rigidity over the cavities 735 of the frame 625 that are filled partially or completely with vacuum, air, and/or other gases.

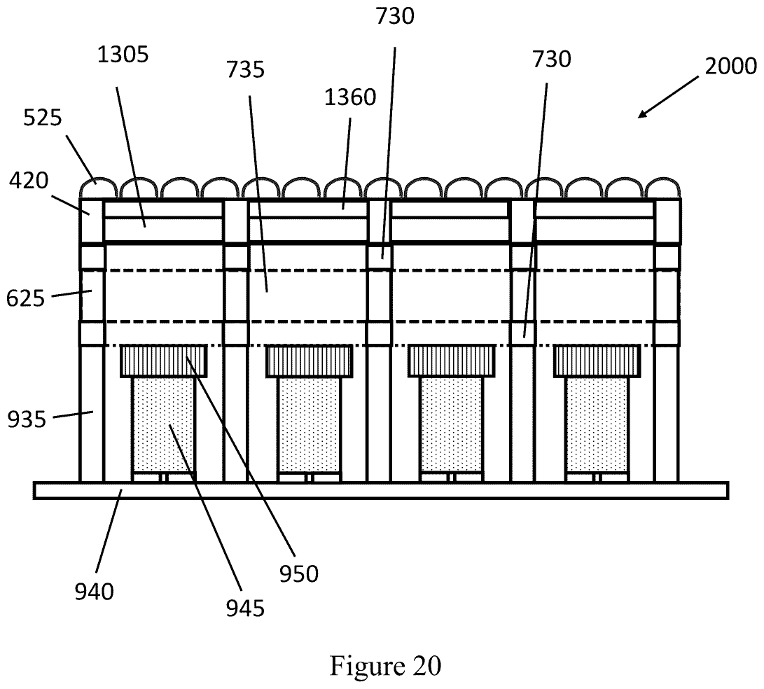

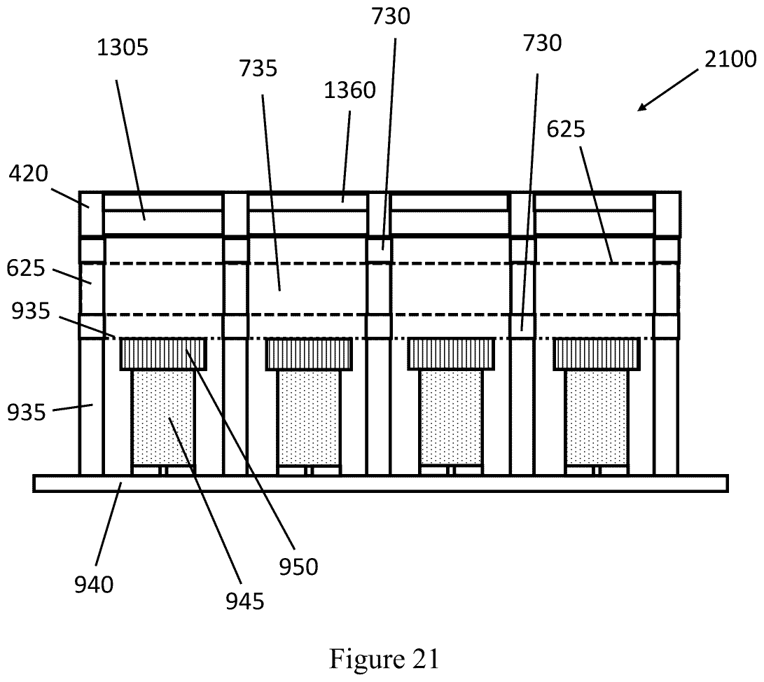

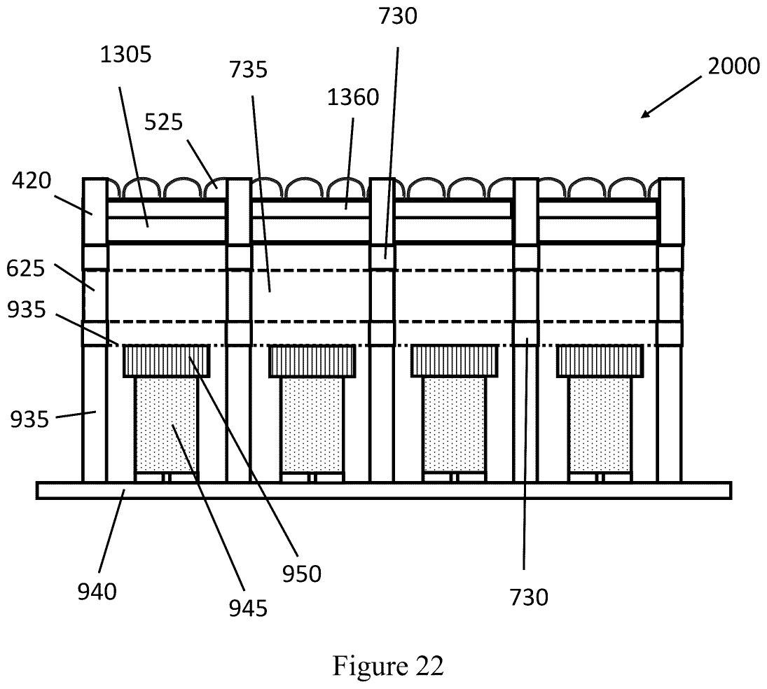

According to embodiments of the invention, processes forming a device may omit the step shown in 1600 at FIG. 16 and result in the device of FIG. 21 rather than FIG. 20. In this process optical element 525 is not disposed on top of reflector 420 and glass layer 1305 and sacrificial layer 1360. Along with the frame 625, the flat surface provided by the glass layer 1305 and sacrificial layer 1360 and reflector 420 may contain the light emitted from the LEDs 945 to narrow the radiation pattern and reduce the light emitting area of the light emitting device.

Alternatively or additionally, the reflector 420 may extend above the support layer 205 or the glass layer 1305 and sacrificial layer 1360 partially or entirely through the optical element 525 to isolate parts of the optical elements 525 (such as lens of a lens array) from each other. This may prevent light from traveling horizontally through the optical element 525.

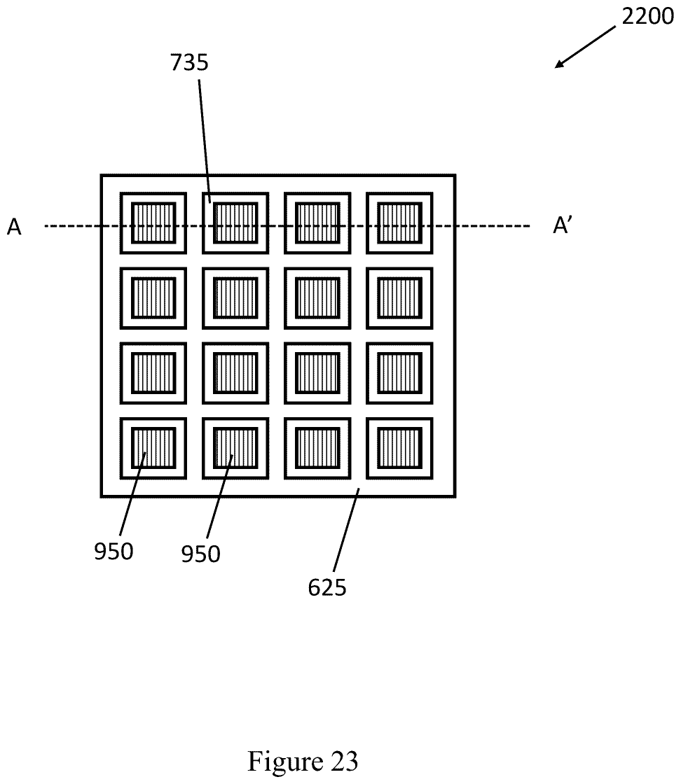

FIG. 23 shows a plan view of a light emitting device according to embodiments of the invention. The frame 625 is a monolithic piece forming cavities 735 within which individual LEDs 945 and wavelength converting layer 950 are disposed. Line A-A′ is where the cross section of previous figures, such as FIG. 21, are taken.

The disclosures provided in this specification are intended to illustrate but not necessarily to limit the described implementation. As used herein, the term “implementation” means an implementation that serves to illustrate by way of embodiments but not limitation. The techniques described in the preceding text and figures can be mixed and matched as circumstances demand to produce alternative implementations. It will be apparent to those of ordinary skill in the art that numerous variations, changes, and substitutions of the embodiments described above can be made without departing from the invention. Furthermore, it shall be understood that all aspects of the invention are not limited to the specific depictions, configurations or relative proportions set forth herein which depend upon a variety of conditions and variables. It should be understood that various alternatives to the embodiments of the invention described herein may be employed in practicing the invention. It is therefore contemplated that the invention shall also cover any such alternatives, modifications, variations or equivalents. All such alternatives will be apparent to one skilled in the art in light of this disclosure and are intended to fall within the scope of the appended claims.

What is claimed is:

1. A light emitting structure comprising:
one or more light emitting devices (LEDs) and LED side walls around the one or more LEDs;
a frame disposed above the one or more LEDs comprising frame side walls having reflective interior surfaces that define sides of one or more cavities; and
a light transmitting structure disposed above the frame and comprising a transparent material disposed directly above at least a portion of the one or more cavities.

2. The light emitting structure of claim 1, wherein the frame is or comprises ceramic.

3. The light emitting structure of claim 1, wherein the frame is or comprises aluminum.

4. The light emitting structure of claim 1, wherein the frame is or comprises silicon.

5. The light emitting structure of claim 1, wherein the transparent material is silicone.

6. The light emitting structure of claim 1, wherein transparent material comprises glass.

7. The light emitting structure of claim 1, wherein the transparent material comprises a glass layer and a silicone layer above the glass layer.

8. The light emitting structure of claim 1, wherein the light transmitting structure comprises reflective sidewalls disposed between segments of the transparent material.

9. The light emitting structure of claim 8, wherein the LED side walls comprise a different material than the reflective sidewalls.

10. The light emitting structure of claim 8, wherein the frame side walls and reflective side walls are spaced apart from each other.

11. The light emitting structure of claim 1, wherein LED side walls are spaced apart from the frame side walls.

12. The light emitting structure of claim 11, wherein the LED side walls are spaced apart from the frame side walls by a silicone layer having a thickness from 1-2 microns.

13. The light emitting structure of claim 1, wherein the light transmitting structure is attached to the frame by a silicone layer having a thickness from 1-2 microns.

14. The light emitting structure of claim 1, wherein the LED side walls comprise a different material than the frame.

15. The light emitting structure of claim 1, further comprising an optical element disposed above the light transmitting structure.

16. The light emitting structure of claim 15, wherein the optical element is at least one of a lens, microlens, metalens, and polarizer.

17. The light emitting structure of claim 1, wherein the one or more light emitting devices is an array of LEDs, the frame is a grid defining a plurality of cavities, and the number of cavities is equal to the number of LEDs in the array.

18. The light emitting structure of claim 1, further comprising:
a plurality of frames and a plurality of light transmitting structures alternately stacked on top of each other above the one or more LEDs,
wherein the plurality of frames comprises the frame and the plurality of light transmitting structure comprises the light transmitting structure.

19. A method of manufacturing a light emitting diode (LED) device comprising:
forming a light transmitting layer comprising transparent material and reflectors disposed between the transparent material;
forming a frame separate from the light transmitting layer;
attaching the frame to the light transmitting layer to form a light narrowing structure; and
attaching the light narrowing structure to an array of LEDs.

20. The method of claim 19, wherein forming the light transmitting layer comprises:
segmenting a silicone sheet to form silicone segments and gaps between the silicone segments;
molding reflective material into the gaps and above the silicone segments; and
planarizing the reflective material.
